(19) United States
(12) Patent Application Publication
(10) Pub. No.: US 2002/0053742 A1
(43) Pub. Date: May 9, 2002

(54) IC package and its assembly method

(76) Inventors: Fumio Hata, Tokyo (JP); Tadashi Kosaka, Atsugi-shi (JP); Hisatane Komori, Kanagawa-ken (JP)

Correspondence Address: FITZPATRICK CELLA HARPER & SCINTO, 30 ROCKEFELLER PLAZA, NEW YORK, NY, 10112, US

(21) Appl. No.: 10/002,229

(22) Filed: Dec. 5, 2001

Related U.S. Application Data
(62) Division of application No. 08/707,046, filed on Aug. 30, 1996.

(30) Foreign Application Priority Data
Sep. 1, 1995 (JP) 7-225296
Sep. 1, 1995 (JP) 7-225297

(51) Int. Cl. H01L 21/44; H01L 23/48; H01L 29/40

(52) U.S. Cl. 257/774; 257/787; 438/112; 438/124; 438/629; 257/692

(57) ABSTRACT

An IC package has a substrate having recesses formed on the side wall thereof, an insulating film for covering an opening of each recess on the side of a principal surface of the substrate, and an IC chip mounted on a mount surface side of the film on the substrate, wherein a conductive portion formed on each recess is used as an external connection terminal for the IC chip. A method of assembling an IC package has the steps of forming a substrate having a plurality of through holes each having an insulating film covering one of the openings of each through hole, mounting one or more IC chips on a principal surface of the substrate on the insulating film side, and electrically connecting the IC chip and the through holes, sealing the substrate with the IC chip mounted thereon with insulating resin, and cut the substrate with the IC chip mounted thereon to expose the side wall of each through hole.

### BACKGROUND OF THE INVENTION

1. Field of the Invention

The present invention relates to a package for integrated circuits and its assembly method.

2. Related Background Art

In order to assemble an IC chip on a circuit board, the IC chip is first assembled in a resin sealed package using a lead frame such as those shown in FIGS. 1 to 5 or in a package with a hollow portion such as shown in FIG. 6.

The assembly method for resin sealed packages shown in FIGS. 1 to 5 will be described.

First, photosensor IC chips are placed on a lead frame (shown in FIG. 1) made of a thin metal plate on which a predetermined circuit pattern is formed through pressing or etching, connections are made by using bonding wires 5 (shown in FIG. 2), and the photosensor IC chips are molded with transparent thermosetting resin 6 (shown in FIG. 3). Thereafter, leads are cut and shaped into a predetermined configuration (shown in FIG. 4). This method is widely adopted because mass production is possible and soldering to a circuit board is relatively easy.

In order to package an IC having a photosensor element, a light transmissive member 9 such as shown in FIG. 5 is bonded in order to prevent damages on a light incidence plane and eliminate unnecessary light reflection (Japanese Patent Laid-open Application No. 63-21878).

For assembly of the package shown in FIG. 6, a photosensor IC chip 4 is placed in a hollow portion 10 of a ceramic or resin mold, connections are made by using bonding wires, and the hollow portion 10 is covered with a light permissive member 9 to hermetically seal it. With this structure, a bonding margin for maintaining the hermetic seal must be prepared, resulting in a large package size.

These conventional methods are associated with various issues to be solved. For example, expensive metal molds are required to be prepared for each type of a package. Production of various types of packages requires immense investment in facilities. It takes a long time to complete a sample which requires new metal molds. Leads are likely to be broken depending upon how the package is dealt with. An additional process for bonding the light permissive member 9 is required and the assembly cost rises.

A package of a lead-less structure has been proposed using a both-side printed circuit board in place of a lead frame (Japanese Patent Laid-open Application No. 2-2150). However, this method uses metal molds like the above methods so that it is associated with similar problems.

### SUMMARY OF THE INVENTION

It is an object of the present invention to provide an IC package and its assembly method capable of dispensing with metal molds, unnecessary for immense investment in facilities even for production of various types of packages, applicable to mass production with low assembly cost, and easy to solder an IC chip to a circuit board.

It is another object of the present invention to solve the above problems and provide an IC package comprising: a substrate having recesses formed on the side wall thereof; an insulating film for covering an opening of each recess on the side of a principal surface of the substrate; and an IC chip mounted on a mount surface side of the film on the substrate, wherein a conductive portion formed on each recess is used as an external connection terminal for the IC chip.

It is an object of the present invention to provide a method of assembling an IC package comprising the steps of: forming a substrate having a plurality of through holes each having an insulating film covering one of the openings of each through hole; mounting one or more IC chips on a principal surface of the substrate on the insulating film side, and electrically connecting the IC chip and the through holes; sealing the substrate with the IC chip mounted thereon with insulating resin; and cut the substrate with the IC chip mounted thereon to expose the side wall of each through hole.

It is another object of the present invention to provide an IC package comprising: a substrate having recesses formed on the side wall thereof; an insulating film for covering an opening of each recess on the side of a principal surface of the substrate; an IC chip mounted on a mount surface side of the film on the substrate; a resin portion for sealing the IC chip; and a rigid member formed on the resin portion, wherein a conductive portion formed on each recess is used as an external connection terminal for the IC chip.

It is another object of the present invention to provide an IC package comprising: a substrate having recesses on the side wall thereof, the recesses being filled with conductive material; an IC chip mounted on one principal surface of the substrate; a transparent resin portion for sealing the IC chip; and a light transmissive member formed on the transparent region portion, wherein the filled conductive material at the side wall of the substrate is used as an external connection terminal for said photosensor IC chip.

It is another object of the present invention to provide a method of assembling an IC package comprising the steps of: forming a substrate having a plurality of through holes each having an insulating film covering one of the openings of each through hole; mounting one or more IC chips on a principal surface of the substrate on the insulating film side, and electrically connecting the IC chip and the through holes; forming a light transmissive member on a transparent resin portion formed on the substrate having the IC chip mounted thereon; and cut the substrate with the IC chip mounted thereon to expose the side wall of each through hole.

It is another object of the present invention to provide a method of assembling an IC package comprising the steps of: forming a substrate having a plurality of through holes each having conductive material filled in the opening of each through hole; mounting one or more IC chips on a principal surface of the substrate on the insulating film side, and electrically connecting the IC chip and the through holes; forming a light transmissive member on a transparent resin portion formed on the substrate having the IC chip mounted thereon; and cut the substrate with the IC chip mounted thereon to expose the conductive material in each through hole.

According to the invention, a plurality of through holes in a printed circuit board are used as external connection terminals, instead of using conventional leads. Therefore, metal molds for lead frames are not required to be prepared for each type of IC chips as in conventional cases.

Since the through hole is covered with an insulating film or filled with conductive material, resin will not flow via the through hole to the back surface of the substrate, it is not necessary to prepare metal molds for stopping a flow of resin.

Since the side wall of the through hole cut vertically or the conductive material in the cut through hole are used as an external connection terminal, leads are broken lesser than conventional leads.

If transparent resin is used when necessary and a light transmissive member having a high rigidity such as glass is placed on the transparent resin, it becomes possible to prevent damages on the surface of the transparent resin and becomes easy to retain optical flatness. An IC package of this invention is preferably used for optical semiconductor elements such as optical sensors, light emitting diodes, and semiconductor lasers.

Since the light permissive member is adhered at the same time when the resin is coated and cured, an increase in the number of processes can be prevented. Furthermore, since an additional margin is not necessary, the outer dimension of the IC package can be made small.

### BRIEF DESCRIPTION OF THE DRAWINGS

FIGS. 1 to 4 are plan views illustrating assembly processes according to conventional techniques.

FIG. 5 is a cross sectional view illustrating an assembly process according to a conventional technique.

FIG. 6 is a cross sectional view of a package according to a conventional technique.

FIGS. 7A and 7B are a perspective view showing the structure of an IC package and a perspective view of a printed circuit board, according to a first embodiment of the invention.

FIG. 8 is a vertical cross sectional view of the IC package taken along line 8-8 of FIG. 7A.

FIGS. 9A and 9B are a perspective view and an enlarged partial view, respectively illustrating the manufacture process for the IC package of the first embodiment.

FIGS. 10A and 10B are a perspective view and an enlarged partial view, respectively illustrating the manufacture process for the IC package of the first embodiment.

FIGS. 11 and 12 are enlarged partial views illustrating the manufacture processes for the IC package of the first embodiment.

FIGS. 13 A and 13 B are a perspective view showing the structure of an IC package and a perspective view of a printed circuit board, according to a second embodiment of the invention.

FIG. 14 is a vertical cross sectional view of the IC package taken along line 14-14 of FIG. 13 A.

FIG. 15 is a perspective view showing the structure of an IC package according to a third embodiment of the invention.

FIG. 16 is a vertical cross-sectional view of the IC package taken along line 16-16 of FIG. 15.

FIGS. 17A and 17B are a perspective view and an enlarged partial view, respectively illustrating the manufacture process for the IC package of the third embodiment.

FIGS. 18A and 18B are a perspective view and an enlarged partial view, respectively illustrating the manufacture process for the IC package of the third embodiment.

FIGS. 19 to 22 are cross sectional views illustrating the manufacture processes for the IC packages of the third embodiment.

FIG. 23 is a perspective view of an IC package according to another embodiment of the invention.

FIG. 24 is a schematic cross sectional view showing a modification of the IC package shown in FIG. 13.

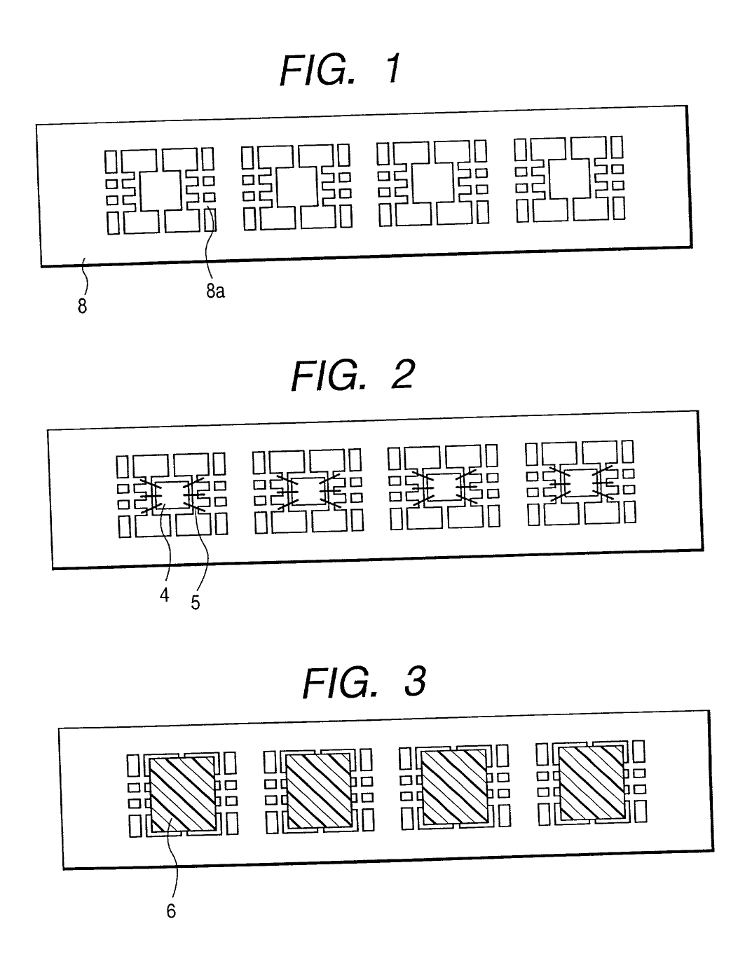

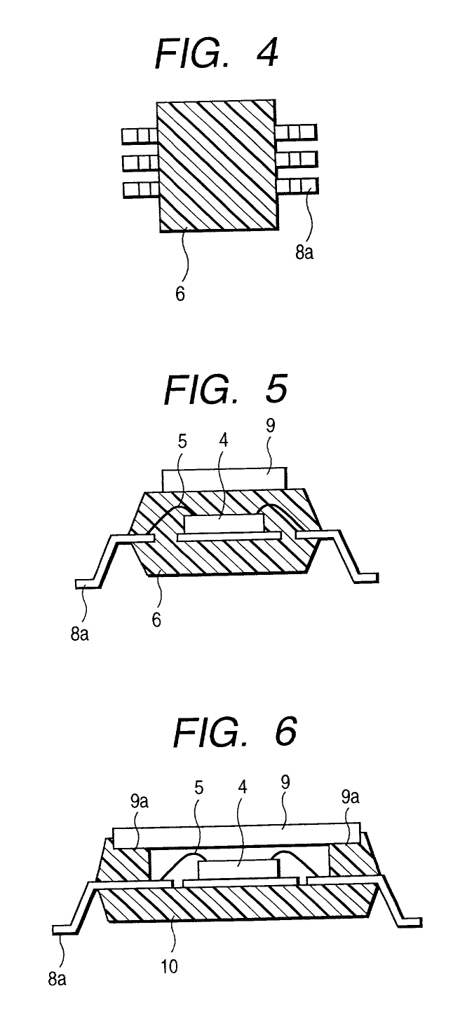

### DETAILED DESCRIPTION OF THE PREFERRED EMBODIMENTS

Embodiments of the present invention will be described in detail with reference to the accompanying drawings.

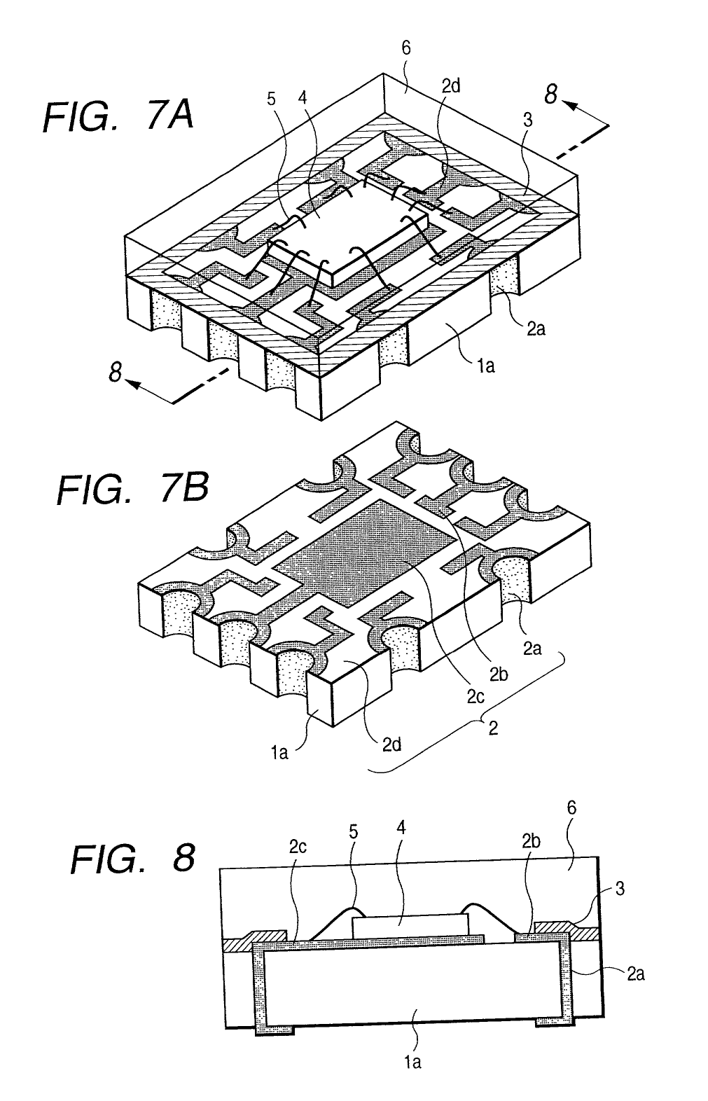

FIGS. 7A and 7B are a perspective view showing the structure of an IC package and a perspective view of a printed circuit board, according to the first embodiment of the invention. FIG. 8 is a vertical cross sectional view of the IC package taken along line 8-8 of FIG. 7A.

In FIGS. 7A and 7B and FIG. 8, reference numeral 1a represents a printed circuit board mounted on which is an IC of a semiconductor memory, a microprocessor, a digital signal processor, a photosensor, a semiconductor laser, an LED, or the like, reference numeral 2 represents a circuit pattern, reference numeral 3 represents an insulating film, reference numeral 4 represents an IC chip, reference numeral 5 represents a bonding wire, and reference numeral 6 represents a sealing resin. The circuit pattern 2 is formed on the printed circuit board 1a and is constituted by a recess portion 2a, a pad portion 2b, an IC chip mount portion 2c, and a wiring portion 2d for connecting these portions. The side wall of the recess portion 2a is plated with solderable metal so that an external circuit can be electrically connected to this soldered area which becomes an external connection terminal. The material of the printed circuit board 1a may be polyimide, glass epoxy resin, or ceramic. In this example, recess portions 2a (formed by cutting the printed circuit board along the center lines of through holes disposed in line) are formed at all four sides of the printed circuit board 1a. The recess portions 2a may be formed at desired positions depending upon the conditions of connections to external circuits. For example, the recess portions 2a may be formed only longer sides of the printed circuit board of a rectangular shape. Through holes not cut may be left in the printed circuit board 1a.

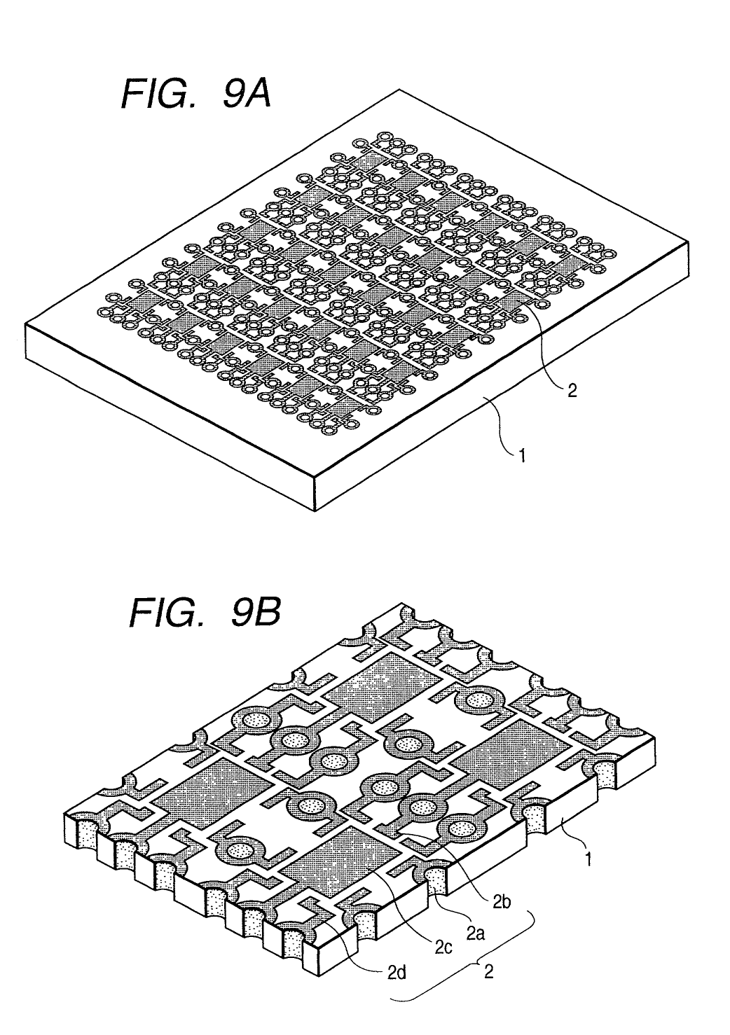

The manufacture method of the IC package will be described with reference to FIGS. 9A and 9B to FIG. 12.

First, a printed circuit board 1 is prepared which is formed with a prescribed circuit pattern 2 as shown in FIGS. 9A and 9B. FIGS. 9A and 9B are a perspective view and an enlarged partial view, respectively of the printed circuit board. The side wall of each through hole of a cylinder or prism shape formed in the printed circuit board has been plated with solderable metal. The circuit pattern 2 is constituted by a through hole portion 2a, a pad portion 2b, an IC chip mount portion 2c, and a wiring portion 2d for connecting these portions. The through holes are disposed in a lattice pattern.

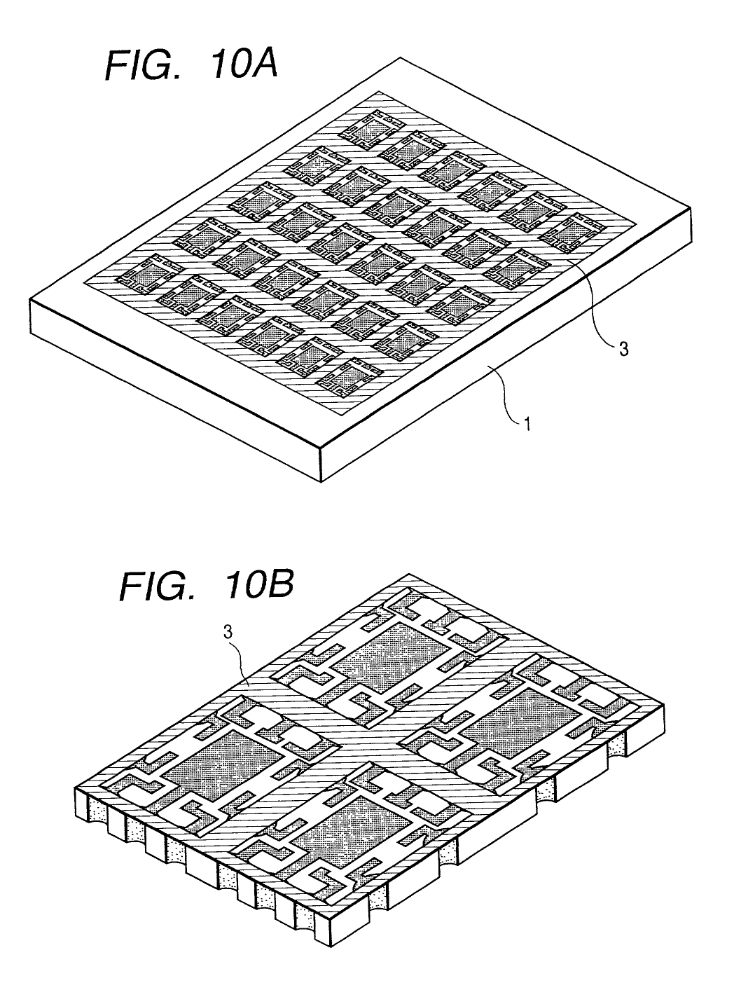

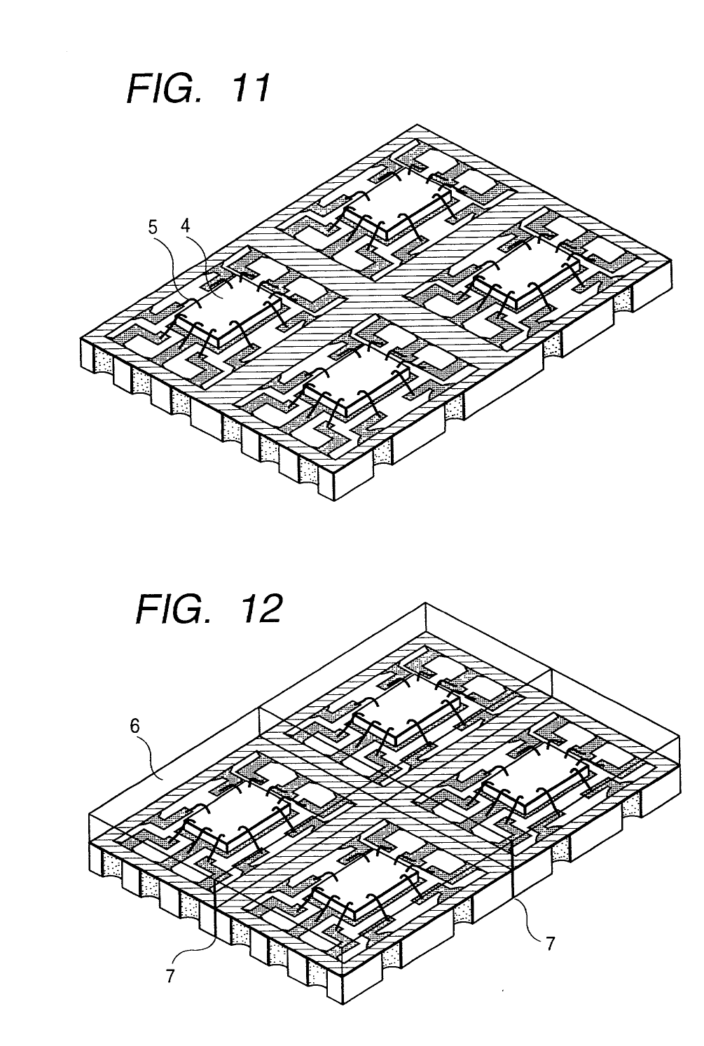

Next, as shown in FIGS. 10A and 10B, an insulating film 3 is adhered covering the openings of all through holes in the printed circuit board 1. FIG. 10A is a perspective view of the printed circuit board 1, and FIG. 10B is an enlarged partial view thereof (FIGS. 11 and 12 show only the enlarged partial views). Some unnecessary areas of the insulating film 3 may be cut in advance in a lattice shape so as to expose the areas of the pad portions 2b and IC chip mount portions 2c, or the insulating film 3 may be adhered first over the whole surface and thereafter unnecessary areas are removed. In this embodiment, the unnecessary areas were removed by the processes of mask exposure and development after a photosensitive resist film was adhered.

Thereafter, as shown in FIG. 11, IC chips are mounted and connected to the circuit pattern 2 by bonding wires 5 through a wire bonding method or the like.

Next, as shown in FIG. 12, liquid sealing resin 6 is coated on the printed circuit board 1 in order to protect the IC chip 4 and bonding wires 5. In this case, since the openings of the through holes are covered with the insulating film 3, the sealing resin 6 will not enter the through holes 2a and flow to the back surface of the printed circuit board 1. It is therefore unnecessary to determine the coating area by using a mold, mold frame, or the like. In this embodiment, although the sealing resin 6 covers the whole surface of the printed circuit board 1, it may cover only the IC chip 4 and bonding wires 5.

After the sealing resin 6 is cured through placement in environmental atmosphere, heating, ultraviolet radiation, or the like, the printed circuit board 1 is cut along a line on which through holes are aligned. In this embodiment, the printed circuit board 1 together with the sealing resin 6 is cut along a line 7 shown in FIG. 12 to obtain each lead-less package such as shown in FIG. 7A having recess portions at the side wall and external connection terminals of the conductive members at the recess portions. In the IC package manufacture method of this embodiment, the IC chips mounted on the printed circuit board may be wire bonded prior to covering the openings of through holes with the insulating film.

As apparent from the above description, an aspect of the present invention resides in that conventional printed circuit board manufacture processes can be used without a use of metal molds for resin sealing and lead frame manufacture.

A lead-less package of this structure can be soldered to external circuits at the recesses 2a by a usual surface mount method (reflow soldering or the like), so that mount is easy and cost effective.

If sealing resin is light transmissive epoxy resin such as NT-8000 (product name) manufactured by Nitto Electric Industry Co. Ltd, and if IC chips of photo-active elements are used such as a photosensor, a light emitting diode, then semiconductor optical devices can be manufactured without using metal molds.

As described so far, according to the first embodiment, a plurality of through holes in a printed circuit board can be used as external connection terminals. Therefore, metal molds for lead frames and resin sealing are not required to be prepared for each type of IC chips as in conventional cases. Accordingly, immense investment in facilities is not necessary even for production of a small number of products of a variety of product types, and even for mass production with low assembly cost.

Since the side walls of the recesses exposed by cutting the printed circuit board along a line of aligned through holes are used as the external connection terminals, the mechanical structure is robust and there is less possibility of breakage.

Next, the second embodiment of the present invention will be described in detail with reference to the accompanying drawing.

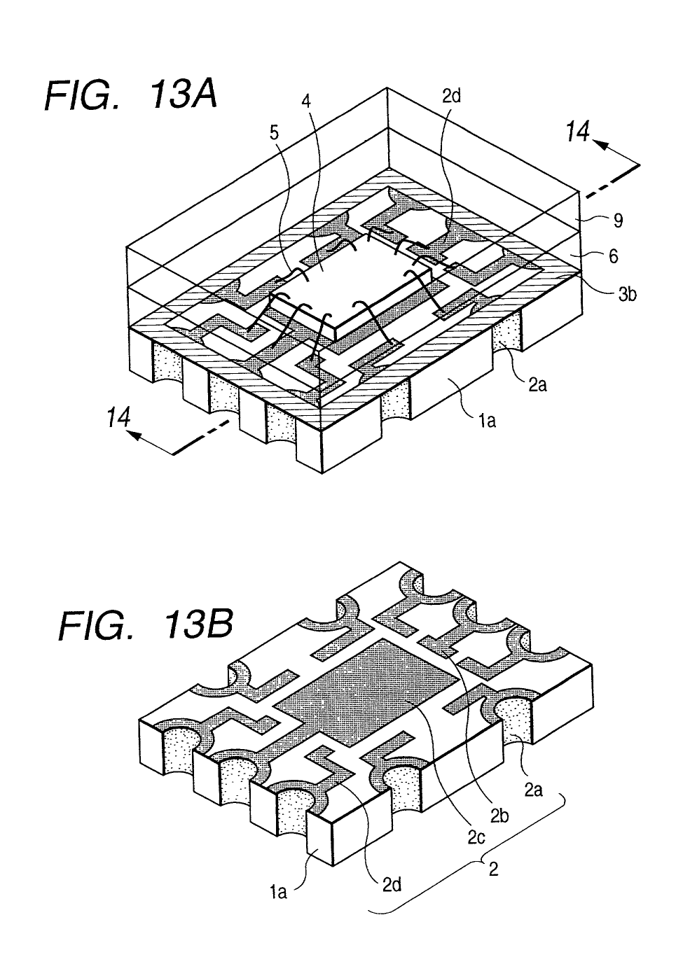

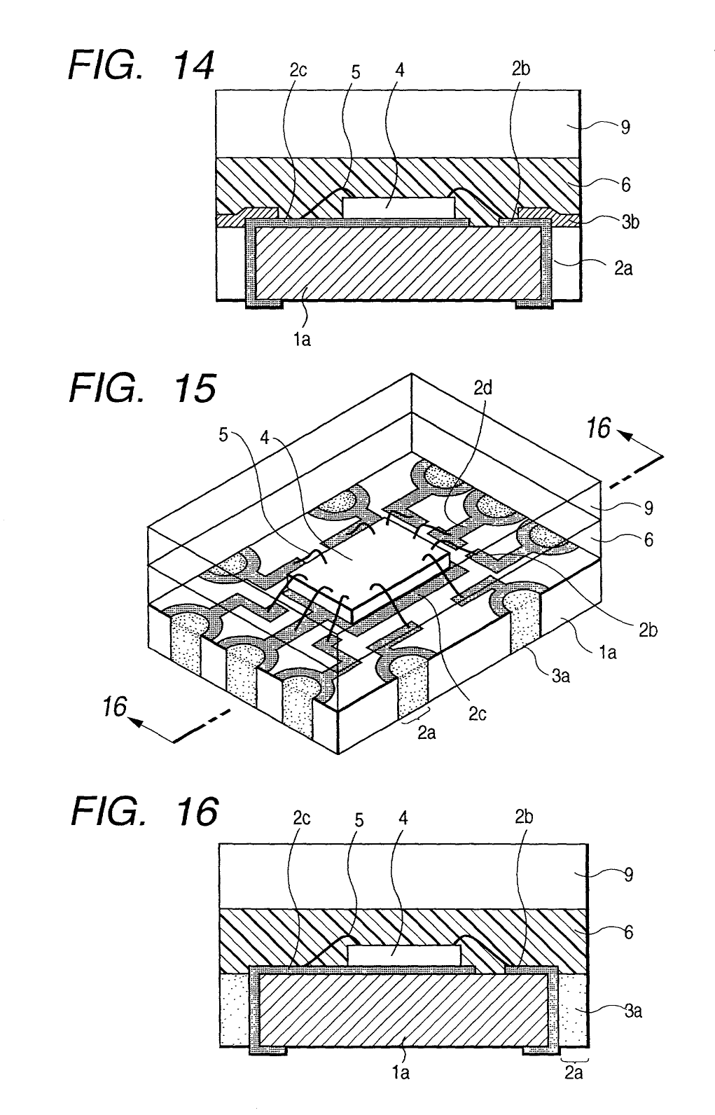

FIGS. 13a and 13b are a perspective view showing the structure of an IC package and a perspective view of a printed circuit board, according to the second embodiment of the invention. FIG. 14 is a vertical cross sectional view of the IC package taken along line 14-14 of FIG. 13 A.

In FIGS. 13 A and 13 B and FIG. 14, reference numeral 1a represents a printed circuit board mounted on which is an IC of a semiconductor memory, a microprocessor, a digital signal processor, a photosensor, a semiconductor laser, an LED, or the like, reference numeral 2 represents a circuit pattern, reference numeral 3 represents an insulating film, reference numeral 4 represents an IC chip, reference numeral 5 represents a bonding wire, reference numeral 6 represents a sealing resin, and reference numeral 9 represents a light permissive member. The circuit pattern 2 is formed on the printed circuit board 1a and is constituted by a recess portion (through hole portion) 2a, a pad portion 2b, an IC chip mount portion 2c, and a wiring portion 2d for connecting these portions. The side wall of the recess portion 2a is plated with solderable metal so that an external circuit can be electrically connected to this soldered area which becomes an external connection terminal. The recess portions are formed by cutting the printed circuit board along the center lines of through holes disposed in line.

FIG. 15 is a perspective view showing the structure of an IC package according to the third embodiment of the invention. FIG. 16 is a vertical cross sectional view of the IC package taken along line 16-16 of FIG. 15.

In FIGS. 15 and 16, reference numeral 1a represents a printed circuit board mounted on which is an IC of a semiconductor memory, a microprocessor, a digital signal processor, a photosensor, a semiconductor laser, an LED, or the like, reference numeral 2 represents a circuit pattern, reference numeral 3 represents an insulating film, reference numeral 4 represents an IC chip, reference numeral 5 represents a bonding wire, reference numeral 6 represents a sealing resin, and reference numeral 9 represents a light permissive member. The circuit pattern 2 is formed on the printed circuit board 1a and is constituted by a through hole portion 2a, a pad portion 2b, an IC chip mount portion 2c, and a wiring portion 2d for connecting these portions. The through hole portion 2a is filled with conductive material 3a so that an external circuit can be electrically connected to this conducive material by soldering, the conductive material becoming an external connection terminal.

The material of the printed circuit board 1a may be polyimide, glass epoxy resin, or ceramic. In the second and third embodiments, through hole portions 2a are formed at all four sides of the printed circuit board 1a. The through hole portions 2a may be formed at desired positions depending upon the conditions of connections to external circuits. For example, the through hole portions 2a may be formed only longer sides of the printed circuit board 1a of a rectangular shape. Through holes not cut may be left in the printed circuit board 1a.

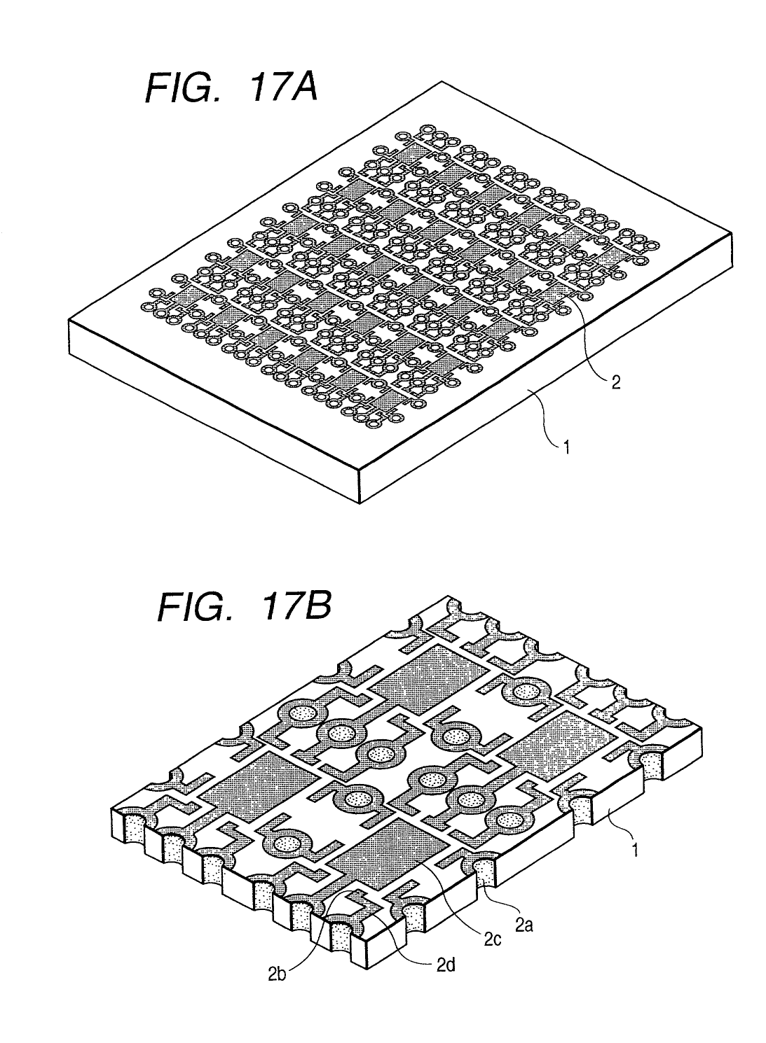

The manufacture method of the IC package will be described with reference to FIG. 17A to FIG. 22. In this method, an IC of a photosensor as a semiconductor optical element is used by way of example.

First, a printed circuit board 1 is prepared which is formed with a prescribed circuit pattern 2 as shown in FIGS. 17A and 17B. FIGS. 17A and 17B are a perspective view and an enlarged partial view, respectively of the printed circuit board. The side wall of each through hole formed in the printed circuit board has been plated with solderable metal. The circuit pattern 2 is constituted by a through hole portion 2a , a pad portion 2b, an IC chip mount portion 2c, and a wiring portion 2d for connecting these portions.

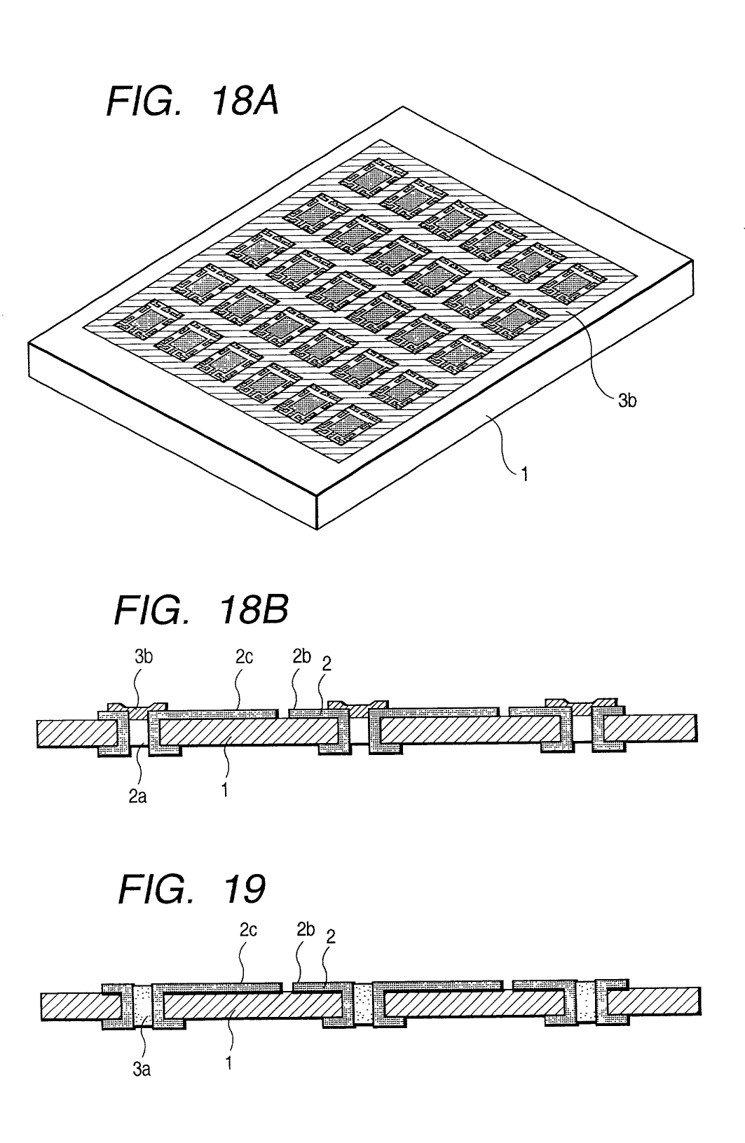

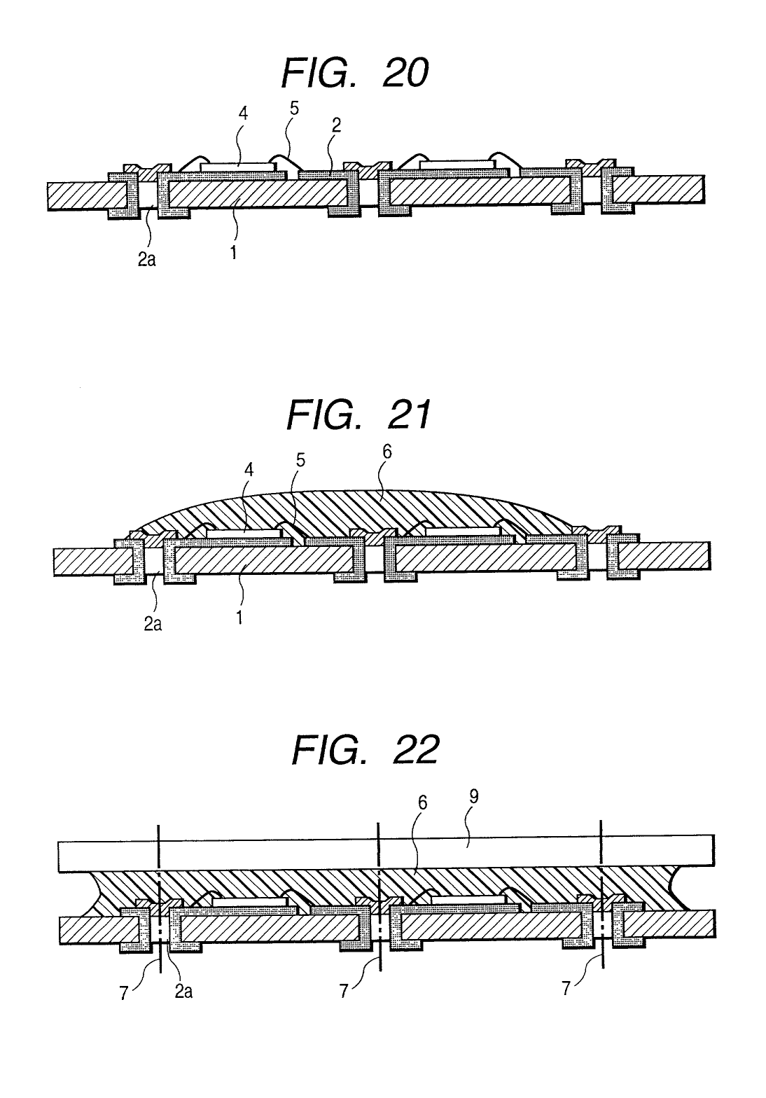

Next, all the through holes in the printed circuit board 1 are filled with conductive material 3a as shown in FIG. 19, or covered with an insulating film 3b. FIG. 18A is a perspective view of the printed circuit board covered with the insulating films, and FIG. 18B is an enlarge partial view in section of the printed circuit board. FIG. 19 is an enlarged partial view in section of the printed circuit board with through holes being filled with conductive material (FIGS. 20 to 22 show only the enlarged partial views in section). Although the through holes are filled with the conductive material 3a after plating, they may be filled by the same single process. In covering the through holes with the insulating film 3b, some unnecessary areas of the insulating film 3b may be cut in advance (for example, in a lattice shape) or it may be adhered first over the whole surface and thereafter unnecessary areas are removed. In this embodiment, the unnecessary areas were removed by the processes of mask exposure and development after a photosensitive resist film was adhered. In FIGS. 20 to 22, for the drawing simplicity, the printed circuit board with through holes being filled with the conductive material 3a is omitted, and only the printed circuit using the insulating film 3b is shown. The same processes are executed for both types of the printed circuit boards.

Thereafter, as shown in FIG. 20, IC chips are mounted and connected to the circuit or lead pattern 2 by bonding wires 5 through a wire bonding method or the like.

Next, as shown in FIG. 21, liquid sealing resin 6 is coated on the printed circuit board 1 in order to protect the IC chip 4 and bonding wires 5. In this case, since the openings of the through holes are filled with the conductive material 3a (not shown) or covered with the insulating film 3, the sealing resin 6 will not enter the through holes 2a and flow to the back surface of the printed circuit board 1. It is therefore unnecessary to determine the coating area by using a mold, mold frame, or the like.

As shown in FIG. 22, prior to curing of the transparent resin 6, the light permissive member 9 is placed on the transparent resin 6 in parallel to the printed circuit board 1 to make the gap between the printed circuit board 1 and light transmissive member 9 be filled with the transparent resin 6.

After the transparent resin 6 is cured through placement in environmental atmosphere, heating, ultraviolet radiation, or the like while the gap between the printed circuit board 1 and light transmissive member 9 is maintained constant by using a jig (not shown) or the like, the printed circuit board 1 is cut along a line on which through holes are aligned. In these embodiments, the printed circuit board 1 together with the sealing resin 6 and light transmissive member 9 is cut along a line 7 such as shown in FIG. 22 to obtain each lead-less package such as shown in FIGS. 13 A to 14 of the second embodiment and each lead-less package such as shown in FIG. 16 of the third embodiment. In the photosensor IC package manufacture method of this embodiment, the IC chips mounted on the printed circuit board may be wire bonded prior to filling in the openings of the through holes.

As apparent from the above description, an aspect of the present invention resides in that conventional printed circuit board manufacture processes can be used without a use of metal molds for resin sealing and lead frame manufacture.

A lead-less package of this structure can be soldered to external circuits by a usual surface mount method (reflow soldering or the like), so that mount is easy and cost effective.

In the above embodiments, BT resin (product name) manufactured by Mitsubishi Gas Chemical Co. Ltd was used for the printed circuit board 1, a photosensitive resist film was used for the insulating film 3b , World Lock No. 801 SE-L and XVL-01L (product names) manufactured by Kyoritsu Chemical Industry Co. Ltd. were used as the transparent resin 6, and a phosphosilicate glass plate was uses as the light transmissive member 9. IC packages excellent in heat resistance of solder and optical performance were able to be manufactured.

If an infrared cut filter made of CM-5000 (product name) manufactured by HOYA CORP. is used in place of the light transmissive member 9, the spectral sensitivity of the photosensor can be adjusted to from the photosensor with desired characteristics. If a specific color is to be cut, colored resin or light permissive member may be used. In the case of an IC not using light, non-light transmissive resin or other materials may be used.

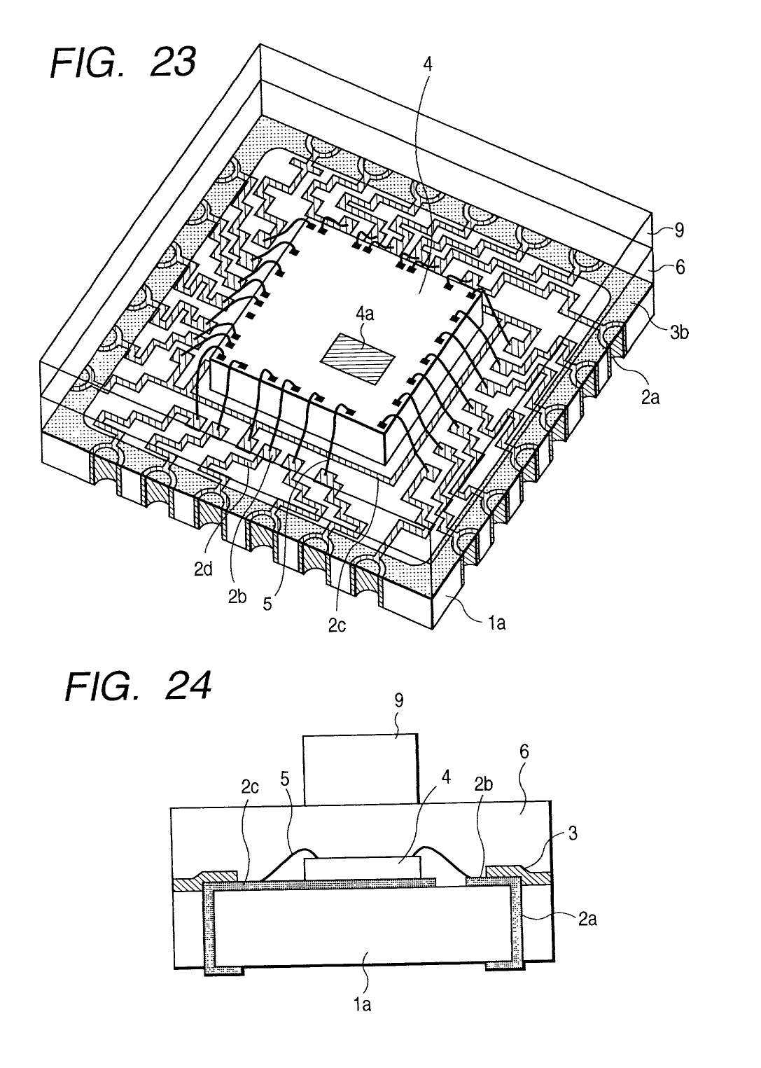

FIG. 23 is a perspective view of an IC package according to another embodiment of the invention.

Recesses 2a to be used as external connection terminals are provided at the four sides of a printed circuit board 1a. An IC chip 4 is disposed on a chip mount portion 2c at the upper surface of the board 1a.

Bonding pads of the IC chip 4 and bonding pad areas of a wiring patter are electrically connected by bonding wires 5.

The length of the wiring pattern 2d is made longer so that corrosion can be avoided which is otherwise caused by water contents entered from the edges of the IC package. In order to dispose a longer wiring pattern in a narrow space, the wiring pattern 2d is deflected at several points as shown in FIG. 23.

Water contents immerse into the package along a conductive wiring pattern. Therefore, if the effective length from the external connection terminal 2a to the bonding pad area 2b is elongated, durability of the IC package can be improved.

Reference numeral 3b represents an insulting film, reference numeral 6 represents resin, and reference numeral 9 represents a protective member.

In this embodiment, an optical active element is used as the IC chip 4, transparent resin was selected as the resin 6, and a light permissive rigid member was selected as the member 9.

For the IC package, particularly an IC package using an optical active element, it is necessary for the thickness (length) from the package surface to the light receiving portion (or light emitting portion) to be relatively thick in order to adversely affected by reflected light (Japanese Patent Laid-open Application No. 63-21878). In this embodiment, the member 9 is adhered to make the thickness between the surface of the member 9 to the light receiving portion 4a thicker.

This IC package can by manufactured by the method illustrated with reference to FIGS. 17A to 22.

If an IC chip with an optical semiconductor device is used, a member may be adhered to the package resin 6, the member 9 may be adhered after each package is cut after curing of the resin, or may be adhered to each cured resin and thereafter each package is cut. Since these methods may lower throughput. Therefore, as described with FIGS. 17A to 22, preferably, after the member 9 is disposed, the resin is cured and then the member 9, cured resin 6, and the printed circuit board 1 are cut at the same time.

As described so far, according to the invention, a plurality of through holes in a printed circuit board can be used as external connection terminals. Therefore, metal molds for lead frames and resin sealing are not required to be prepared for each type of IC chips as in conventional cases. Accordingly, immense investment in facilities is not necessary even for production of a small number of products of a variety of product types, and even for mass production with low assembly cost.

Since the soldering margin for the light transmissive member is not necessary, the outer dimension of the IC package can be made very small.

Since the side walls of the recesses exposed by cutting the printed circuit board along a line of aligned through holes are used as the external connection terminals, the mechanical structure is robust and there is less possibility of breakage.

What is claimed is:

1. An IC package comprising:
a substrate having recesses formed on the side wall thereof;
an insulating film for covering an opening of each said recess on the side of a principal surface of said substrate; and
an IC chip mounted on a mount surface side of said film on said substrate,
wherein a conductive portion formed on each said recess is used as an external connection terminal for said IC chip.

2. An IC package according to claim 1, wherein the whole principal surface of said IC chip on the IC chip mount side is sealed with insulating resin.

3. An IC package according to claim 1, wherein said insulating film covers only the opening and its peripheral area.

4. An IC package according to claim 1, wherein said substrate has a circuit pattern including a pad portion for electrical connection to said IC chip, an IC chip mount portion, and a wiring portion for connection of said pad portion and said IC chip mount portion to the conductive portion.

5. A method of assembling an IC package comprising the steps of:
forming a substrate having a plurality of through holes each having an insulating film covering one of the openings of each through hole;
mounting one or more IC chips on a principal surface of the substrate on the insulating film side, and electrically connecting the IC chip and the through holes;
sealing the substrate with the IC chip mounted thereon with insulating resin; and
cut the substrate with the IC chip mounted thereon to expose the side wall of each through hole.

6. A method according to claim 5, wherein said step of electrically connecting the IC chip to the through holes performs wire bonding between the IC chip and pad portions connected to the through holes.

7. A method according to claim 5, wherein the IC chip has an optical active element and the insulating resin is light permissive resin.

8. A method according to claim 5, wherein the plurality of through holes are disposed in a lattice shape.

9. An IC package comprising:
a substrate having a concave side;
an insulating film sealing an opening at the concave side of said substrate;
IC chip mounted on a side of said substrate, on which said film is arranged;
a resin sealing said IC chip; and
a rigid member provided on said resin;
wherein a conductive section formed in the concave side is used as an external connection terminal of the IC chip.

10. An IC package comprising:
a substrate having, at a side, a cut through hole filled with a conductive material;
a photosensor IC chip mounted on one major surface of said substrate;
a transparent resin sealing said photosensor IC chip; and
a right transmitting member provided on said transparent resin,
wherein the conductive member at the side of said substrate is used as an external connection terminal of said photosensor IC chip.

11. A method for producing a photosensor IC package comprising steps of:
forming a substrate having a through holes of which openings at one side are sealed with an insulating film;
mounting one or more the photosensor IC chips on a major surface of the substrate, on which the film is arranged;
providing a light transmitting member through a transparent resin on the substrate on which the photosensor IC chip is mounted; and
cutting the substrate on which the photosensor IC chip is mounted, so that a wall of the through holes are exposed.

12. A method for producing a photosensor IC chip comprising steps of:
forming a substrate having plural through holes of which openings are filled with a conductive material;
mounting on one major surface of the substrate, one or more photosensor IC chips, and connecting electrically the photosensor IC chips with the through holes;
providing on the substrate on which the photosensor IC chip is mounted, a light transmitting member through a transparent resin; and
cutting the substrate on which the photosensor IC chip is mounted, so that the conductive material in the through hole is exposed.

13. A method according to claim 11 or 12, wherein the plurality of through holes are disposed in a lattice shape.

14. An IC package according to claim 1, wherein said recess has a curved surface.

15. An IC package according to claim 1, wherein said recess is of a cut cylinder shape.

16. An IC package according to claim 1, wherein said recess is of a cut prism shape.

17. An IC package according to claim 1, wherein said recess is a cut through hole.

18. An IC package according to claim 1, wherein a rigid member is disposed on said insulating resin.

19. An IC package according to claim 1, wherein said IC chip is an optical active element, and said insulating resin is transparent and has a light transmissive member formed on the surface thereof.

20. An IC package according to claim 1, wherein the surface of said insulating resin is mounted with a light transmissive member having generally the same area as that of said substrate.

21. A method according to claim 5, wherein the IC chip is an optical semiconductor element, the insulating resin is transparent resin, and the method further comprising the step of forming a light transmissive member on the insulating resin.

22. A method according to claim 5, further comprising the step of forming a rigid member on the cured insulating resin.

23. A method according to claim 5, wherein after a rigid member is disposed on the insulating resin, the insulating resin is cured and the substrate is cut.

24. A method according to claim 5, wherein after a rigid member is disposed on the insulating resin, the substrate as well as the insulating resin is cut.
